(19) United States
(12) Patent Application Publication
(10) Pub. No.: US 2018/0083098 A1
(43) Pub. Date: Mar. 22, 2018

(54) RF DEVICE WITH REDUCED SUBSTRATE COUPLING

(71) Applicant: QUALCOMM Incorporated, San Diego, CA (US)

(72) Inventor: Sinan GOKTEPELI, San Diego, CA (US)

(21) Appl. No.: 15/272,335

(22) Filed: Sep. 21, 2016

(51) Int. Cl. H01L 29/06; H01L 27/12; H01L 23/66; H01L 21/762; H01L 21/84

(52) U.S. Cl. CPC H01L 29/0649; H01L 27/1211; H01L 2223/6616; H01L 21/76289; H01L 21/845; H01L 23/66

(57) ABSTRACT

A substrate is provided with at least one etch stop layer to line a cavity after etching of the substrate. The cavity isolates the substrate from an active layer including a plurality of transistors.

### TECHNICAL FIELD

This application relates generally to transistors, and more particularly to semiconductor devices with reduced substrate coupling between the transistors and the substrate.

### BACKGROUND

In a silicon-on-insulator device, the transistors are formed in an active layer over a buried oxide layer. The buried oxide layer isolates the active layer from an underlying substrate. Although this isolation is substantial, a semiconductor such as silicon will tend to have free carriers at interfaces with the buried oxide layer. These free carriers create a strong non-linear response in RF devices such as switches, inductors, low noise amplifiers, power amplifiers, and capacitors from the resulting capacitive coupling between the free carriers and these components. In particular, the coupling undesirably accentuates the second and third harmonics of the RF signal conducted by the affected devices.

A conventional way to address the non-linear coupling is by replacing the silicon substrate with a dielectric such as in a silicon-on-sapphire approach. But such an approach is very costly and difficult to manufacture. Alternatively, the silicon substrate may include a trap-rich layer to interface with the buried oxide layer. In yet another approach, layer transfer processes are used in which the substrate is removed from the buried oxide layer and replaced with a top-side handle wafer above the dielectric and metal layers produced in the backside-end-of-line (BEOL) processing. But such a handle wafer will also undesirably couple with the RF components such that it may be further isolated through a trap-rich layer. However, the trap-rich layer isolation does not fully cure the non-linear coupling regardless of whether a layer transfer process is used or not. The resulting second and third harmonics of the RF signal tend to be very undesirable due to, for example, Federal Communications Commission requirements that limit the amount of RF energy that may be leaked outside of the licensed band.

There is thus a need in the art for greater isolation for semiconductor-on-insulator architectures.

### SUMMARY

To provide improved isolation between the active devices in a semiconductor-on-insulator architecture, an etch stop layer is provided between an intervening portion of the semiconductor substrate and the buried oxide layer. The etch stop layer is thus separated from the buried oxide layer by the intervening portion of substrate. The buried oxide layer includes a plurality of through-buried-oxide-layer vias through which the intervening portion of the substrate is etched away. An active layer on the buried oxide layer is thus separated from the etch stop layer by the free space of a cavity. Alternatively, the free space may be filled or partially filled with dielectric material.

The substrate is thus isolated from the active layer on the buried oxide layer by the free space of the cavity and the etch stop layer. The free space isolates the substrate from the RF signals conducted through the devices in the active layer and also through the metal layers above the active layer. Accordingly, the non-linear coupling that produced second and third harmonics in conventional semiconductor-on-insulator architectures is eliminated.

In an alternative embodiment, the substrate does not include a buried oxide layer. Instead, a second etch stop layer is used to define the portion of substrate that will be removed by etching to form the cavity.

These and additional advantages may be better appreciated through the following detailed description.

### BRIEF DESCRIPTION OF THE DRAWINGS

FIG. 1 is a cross-sectional view of a semiconductor-on-insulator device in which the active layer and buried oxide layer are separated from the etch stop layer by a cavity in accordance with an aspect of the disclosure.

FIG. 2A illustrates the implantation of the etch stop layer during the manufacture of the device of FIG. 1.

FIG. 2B illustrates the device of FIG. 2A after formation of the transistors in the active layer.

FIG. 2C illustrates the device of FIG. 2B after formation of vias through the buried oxide layer into the intervening substrate portion between the buried oxide layer and the etch stop layer.

FIG. 2D illustrates the device of FIG. 2C after the intervening substrate portion is etched away through the vias in the buried oxide layer.

FIG. 3 is a cross-sectional view of a semiconductor-on-insulator device in which the active layer and buried oxide layer are separated from the substrate by a cavity laterally bounded by a deep separation dielectric in accordance with an aspect of the disclosure.

FIG. 4 is a cross-sectional view of a semiconductor device in which the cavity is bounded by an upper etch stop layer and a lower etch stop layer in accordance with an aspect of the disclosure.

FIG. 5 is a flowchart for a method of manufacturing an RF device-on-nothing in accordance with an aspect of the disclosure.

Embodiments of the present invention and their advantages are best understood by referring to the detailed description that follows. It should be appreciated that like reference numerals are used to identify like elements illustrated in one or more of the figure.

### DETAILED DESCRIPTION

A semiconductor-on-substrate device is provided that includes a cavity between a buried oxide layer and an etch stop layer. The buried oxide layer supports an active layer containing transistors and includes a plurality of through vias through which an intervening portion of a substrate between the etch stop layer and the buried oxide layer is etched away to form the cavity. A remainder of the substrate is protected from the etching by the etch stop layer. The cavity may comprise free space filled with air or be partially filled with a dielectric material. Regardless of whether the cavity is partially filled with dielectric material or not, the resulting isolation between the remainder of the substrate and the active layer substantially eliminates parasitic coupling between the remaining substrate and the active layer. Transistors in the active layer may thus conduct RF signals without the generation of undesirable second and third harmonics from any parasitic coupling with the substrate.

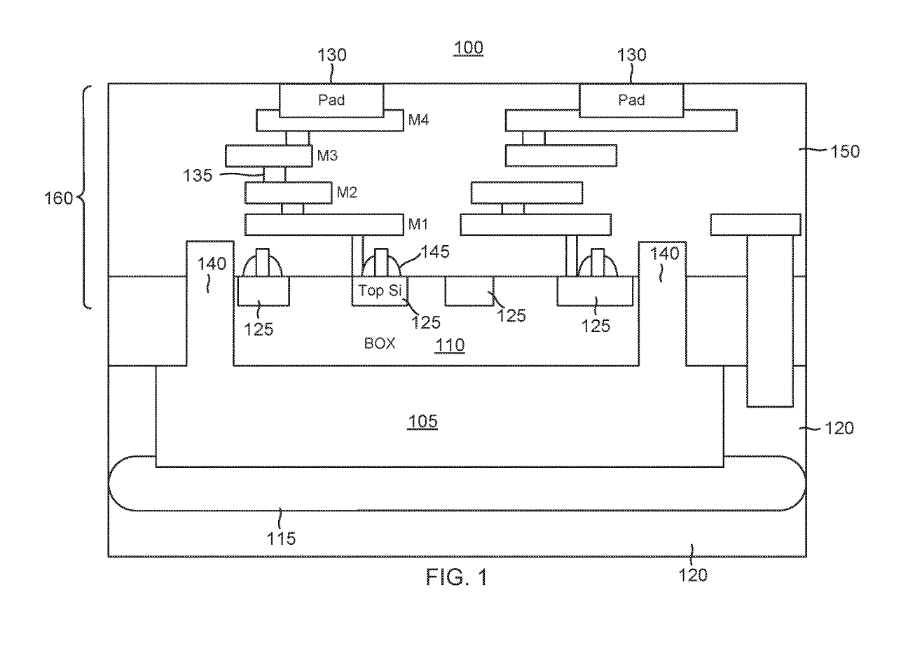

The substrate in the following example embodiments is silicon such that the semiconductor-on-insulator architecture is a silicon-on-insulator architecture. But it will be appreciated that the devices and techniques disclosed herein may be readily adapted to other semiconductor substrates such as III-V semiconductor substrates. An example silicon-on-insulator device 100 is shown in FIG. 1. In device 100, a cavity 105 separates a buried oxide (BOX) layer 110 from an etch stop layer 115 in a substrate 120. Buried oxide layer 110 supports an active layer 160 including a silicon layer 125 in (and on) which are formed transistors 145. Buried oxide layer 110 includes a plurality of through vias 140 that extend through buried oxide layer 110 into cavity 105.

Active layer 160 also include a plurality of metal layers such as metal layers M1, M2, M3, and M4 that are separated by dielectric material 150. The metal layers couple together through a plurality of vias 135 to transistors 145 as well as to pads 130 so that signals may be driven into and out of device 100. Should these signals be RF signals, the resulting electrical activity would tend to undesirably parasitically couple with substrate 120. But this coupling is substantially eliminated by cavity 105 without the complication and expense of processing steps such as the introduction of a trap-rich layer. Moreover, the isolation provided by cavity 105 offers greater reduction of second and third harmonics of the RF signals than conventional trap-rich layer approaches. In addition, this isolation avoids the expense and complication of exotic substrate architectures such as silicon-on-sapphire architectures.

Etch stop layer 115 may be formed using an epitaxial deposition process or through ion implantation. In an epitaxial deposition, etch stop layer 115 would be deposited on a portion of substrate 120. An additional epitaxial deposition of another portion of substrate 120 would then cover etch stop layer 115 prior to the deposition of buried oxide layer 110. Buried oxide layer 110 covers this portion of substrate 120 and in turn is covered by an active layer 160 that includes a device layer of silicon 125 in which transistors 145 are formed. The manufacture of silicon-on-insulator device 100 will now be explained in more detail with regard to an ion implantation process for forming etch stop layer 115.

Silicon-On-Insulator with Cavity Isolation Manufacture

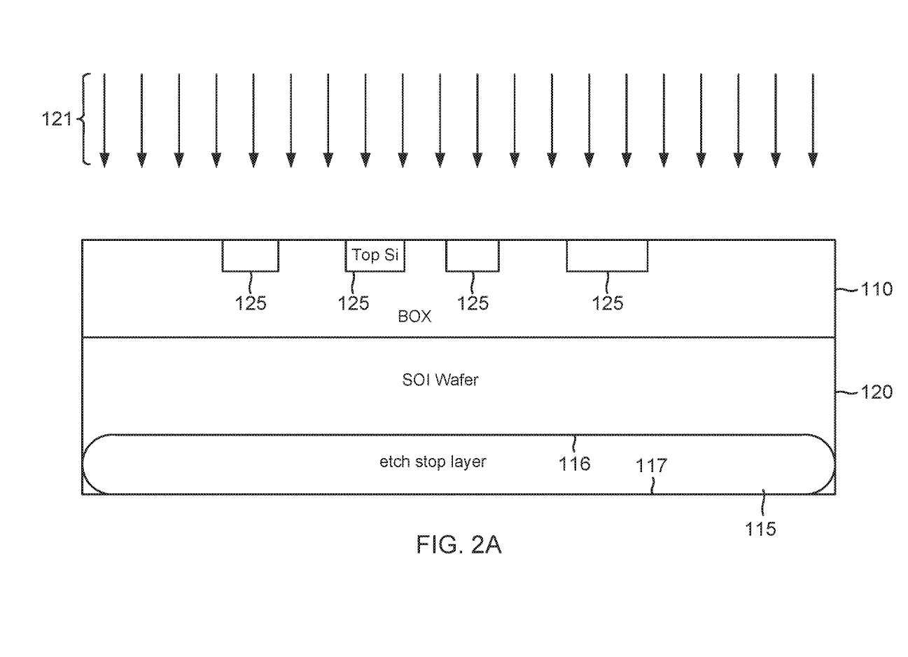

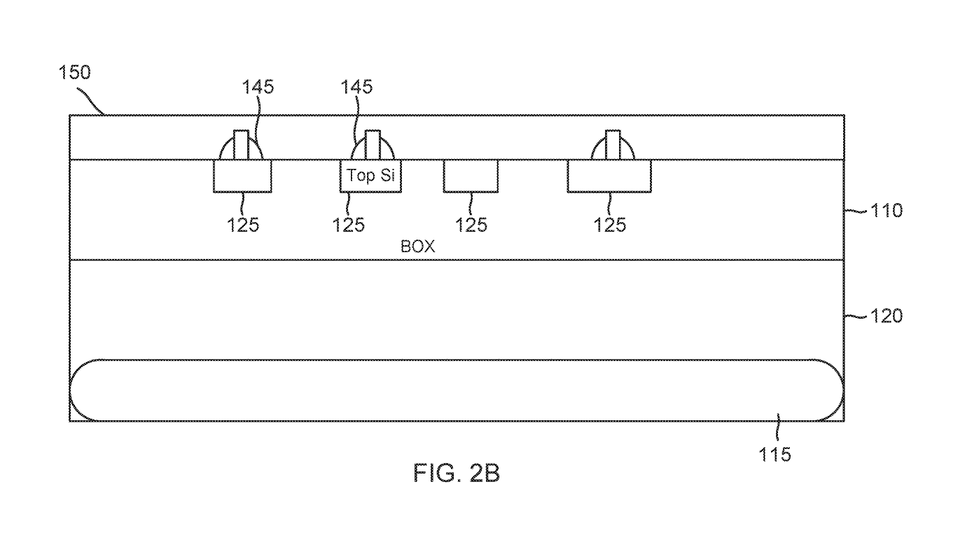

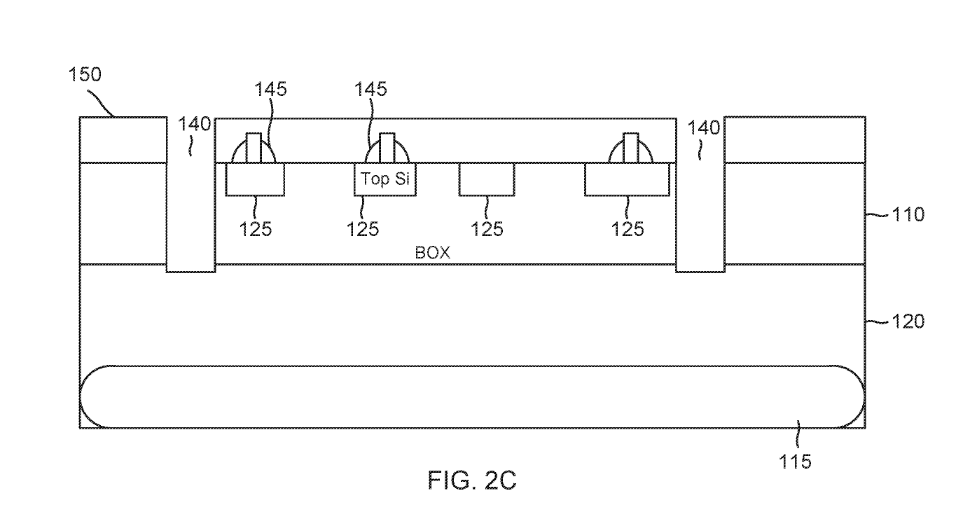

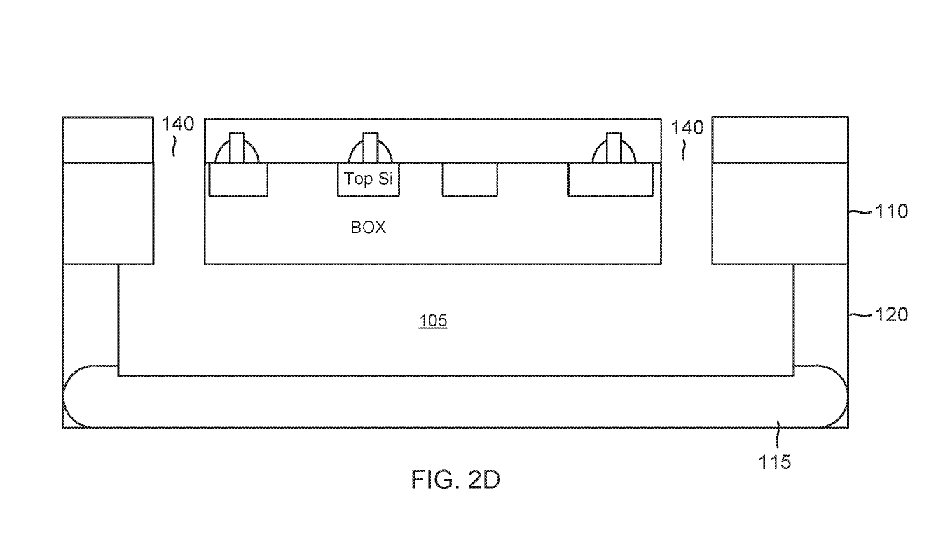

A silicon wafer or substrate 120 is processed such as through conventional silicon-on-insulator techniques to include a buried oxide (BOX) layer 110 that separates substrate 120 from a device silicon layer 125 (which may also be denoted as a top silicon layer) as shown in FIG. 2A. Prior to the formation of transistors 145 (FIG. 1), substrate 120 is implanted with ions 121 to form etch stop layer 115. For example, suitable ions 121 include boron, germanium, and boron/germanium. Alternatively, etch stop layer 115 may be epitaxially deposited as discussed earlier. Etch stop layer 115 includes a device-facing surface 116 that faces an intervening portion of substrate 120 that intervenes between etch stop layer 115 and buried oxide layer 110. In addition, etch stop layer has a substrate-facing surface 117 that faces the remainder of substrate 120 (shown in FIG. 1). It is believed that a mid 10¹⁵ boron implantation is sufficient. The energy of the implantation is adjusted so that that the projected range (Rp) of the implantation leaves a sufficient portion of substrate 120 intervening between the implantation Rp and buried oxide layer 110. It is this intervening portion of substrate 120 that will be removed to form cavity 105 (FIG. 1) as discussed further herein.

With etch stop layer 115 completed, transistors 145 may be formed on device silicon layer 125 as shown in FIG. 2B. Although transistors 145 are fin-shaped transistors (FinFETs), it will be appreciated that conventional planar CMOS transistors also benefit from the cavity isolation disclosed herein. Moreover, transistors 145 may also be implemented as nanowire devices. An inter-layer dielectric layer 150 covers transistors 145.

After transistors 145 are completed and covered with inter-layer dielectric (ILD) 150, through vias 140 are formed as shown in FIG. 2C. Through vias 140 extend through ILD layer 150 and through buried oxide layer 110 into the intervening portion of substrate 120 that intervenes between buried oxide layer 110 and etch stop layer 115. For example, a reactive ion etch process may be used to form through vias 140.

A wet etch process may then be used to etch away the intervening portion of substrate 120 between buried oxide layer 110 and etch stop layer 115 to form cavity 105 as shown in FIG. 2D. For example, a tetramethylammonium hydroxide (TMAH) etch may be used to form cavity 105 since it selectively etches silicon as opposed to ion-implanted etch stop layer 115. In that regard, boron-doped silicon etches very slowly with TMAH whereas undoped silicon etches much faster. Cavity 105 is thus readily etched away without any significant etching of etch stop layer 115.

Referring back to FIG. 1, active layer 160 may then be completed using a standard back-end-of-line (BEOL) process. In a BEOL process, transistors 145 get interconnected through the deposition and patterning of metal layers such as metal layers M1, M2, M3, and M4 as interconnected through vias 135. The metal layers are separated by additional depositions of IDL layers 150. The BEOL process also includes the formation of chip bonding sites such as pads 130.

Transistors 145 in silicon-on-insulator device 100 may advantageously conduct RF signals without the excitation of second and third harmonics due to the isolation provided by cavity 105 that isolates transistors 145 (as well as metal layers M1 through M4 and associated vias 135) from parasitically coupling with the remainder of substrate 120 below etch stop layer 115. Moreover this isolation is more effective than the use of trap-rich layers and can be produced at lower cost.

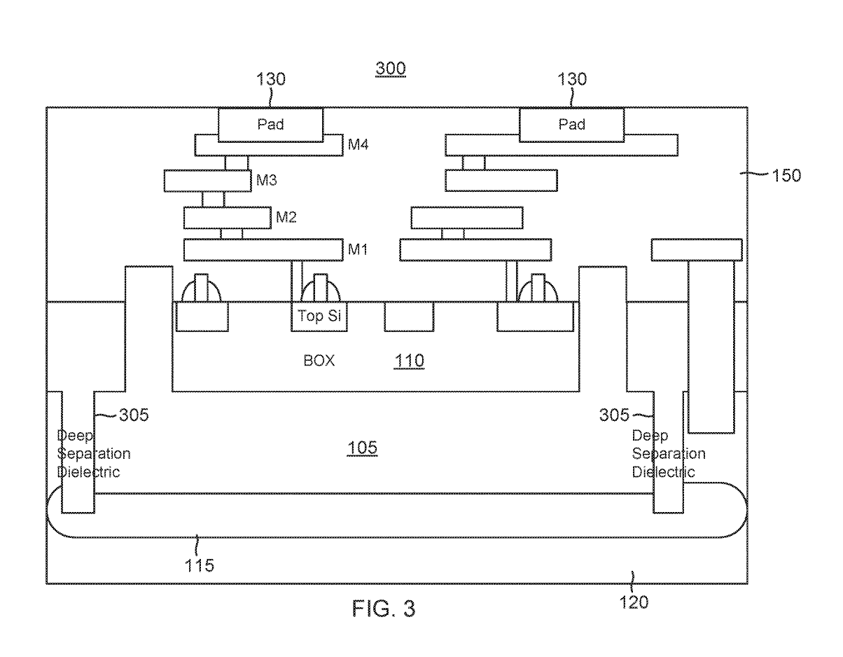

To better limit the lateral etching of cavity 105, it may be laterally demarcated by deep separation dielectric trenches 305 as shown in FIG. 3 for a silicon-on-insulator device 300. Silicon-on-insulator device 300 includes the same structures as discussed with regard to silicon-on-insulator device 100 except for deep separation dielectric trenches 305. Referring to FIG. 2A, dielectric trenches 305 (not illustrated) may be formed in substrate 120 using, e.g. analogous lithography, dry etch, and trench filling with oxide steps as employed in conventional shallow trench isolation techniques. In an alternative embodiment, a masked ion implant step may be used to replace dielectric trenches 305 with a second etch stop layer. Such an ion implantation step would be conducted at lower energy than the ion implantation used to form etch stop layer 115.

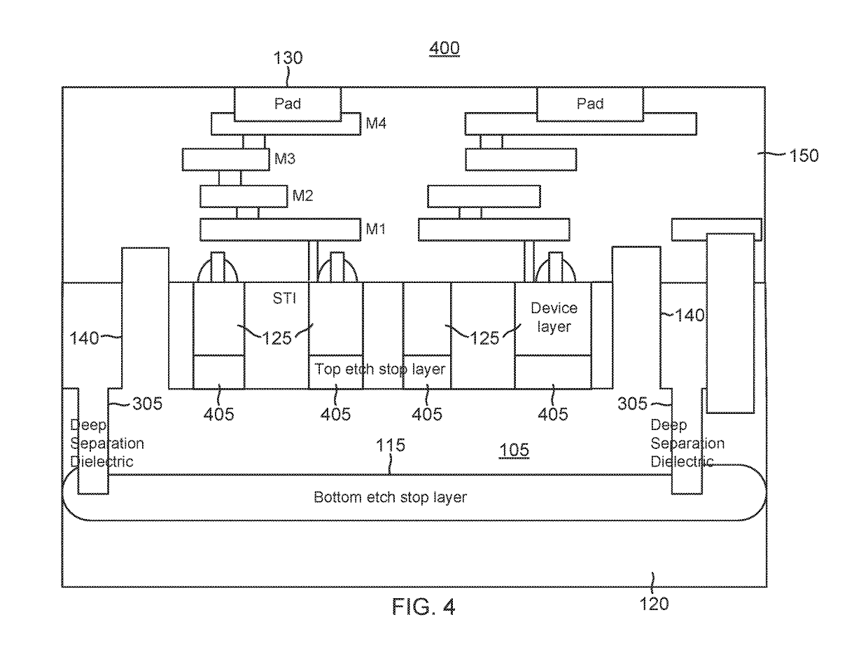

The use of a buried oxide layer may be eliminated by introducing a top etch stop layer 405 as shown for a semiconductor device 400 of FIG. 4. The transistors on active silicon layer 125 are isolated through shallow trench isolation (STI) regions. Cavity 105 is thus not only laterally limited by deep dielectric trenches 305 but also limited in the z dimension by top etch stop layer 405 and (bottom) etch stop layer 115. Etch stop layers 405 and 115 may be ion implanted or epitaxially deposited. Top etch stop layer 405 may be deeper or shallower than the STI regions. In device 400, top etch stop layer 405 is shallower than the STI regions such that it assists in isolating the transistors. It will be appreciated that the inclusion of a deep dielectric trenches 305 in STI embodiments such as device 400 is optional. A method of manufacturing a semiconductor-on-insulator device with cavity isolation will now be discussed.

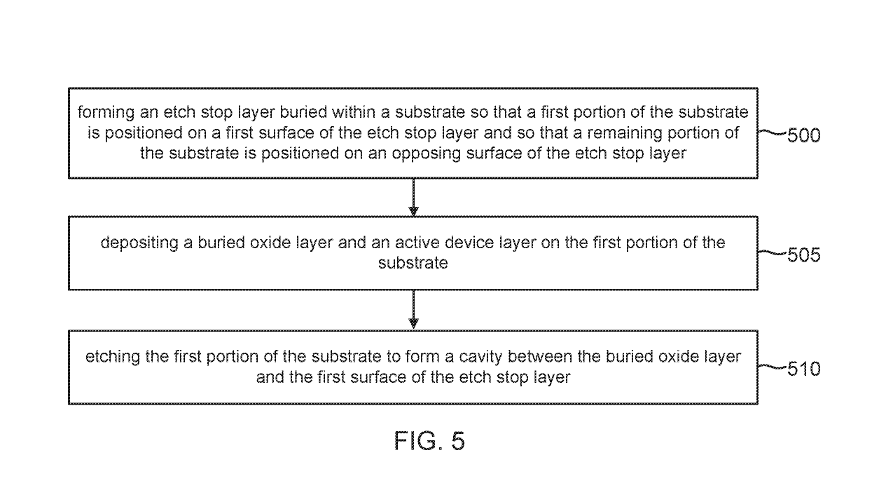

The method of manufacture as shown in the flowchart of FIG. 5 includes an act 500 of forming an etch stop layer buried within a substrate so that a first portion of the substrate is positioned on a first surface of the etch stop layer and so that a remaining portion of the substrate is positioned on an opposing surface of the etch stop layer. An example of act 500 is the formation of etch stop layer 115 with opposing surfaces 116 and 117 as discussed with regard to FIG. 2A.

The method also includes an act 505 of forming a buried oxide layer and an active device layer on the first portion of the substrate. The formation of buried oxide layer 110 and silicon device layer 125 is an example of act 505. It will be appreciated that if an ion implantation step is used to form etch stop layer 115, act 500 is performed after act 505. Conversely, should etch stop layer 115 be epitaxially deposited, act 500 would be performed prior to act 505.

Finally, the method includes an act 510 of etching the first portion of the substrate to form a cavity between the buried oxide layer and the first surface of the etch stop layer. The etching of cavity 105 as discussed with regard to FIG. 2D is an example of act 510.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1. A semiconductor-on-insulator (SOI) device, comprising:
a semiconductor layer including a plurality of transistors, the semiconductor layer including an active surface and a buried surface;
a buried oxide layer, wherein the buried oxide layer surrounds the buried surface of the semiconductor layer;
a cavity; and
an etch stop layer in a substrate, wherein a first surface of the etch stop layer faces the cavity and a second surface of the etch stop layer faces the substrate.

2. The SOI device of claim 1, wherein the buried oxide layer includes a plurality of through vias extending into the cavity.

3. The SOI device of claim 1, wherein the substrate comprises silicon and the etch stop layer is an ion-implanted silicon layer in the substrate.

4. The SOI device of claim 3, wherein the ion is selected from the group consisting of boron and germanium.

5. The SOI device of claim 1, further comprising a deep dielectric trench configured to laterally isolate the cavity.

6. The SOI device of claim 1, wherein the plurality of transistors comprises a plurality of fin-shaped field effect transistors.

7. The SOI device of claim 1, wherein the semiconductor layer is part of an active layer including a plurality of metal layers interconnected by a plurality of vias.

8. The SOI device of claim 1, wherein the transistors are RF transistors, and wherein the cavity is configured to isolate the substrate from parasitically coupling with an RF signal transmitted by the RF transistors.

9. The SOI device of claim 1, wherein the cavity is filled with air.

10.-20. (canceled)
